(19) United States
(12) Patent Application Publication
(10) Pub. No.: US 2025/0314368 A1
(43) Pub. Date: Oct. 9, 2025

(54) OPTICAL CONTRACTILE UNIT LCE WITH LEDS, SUCH AS μLEDS

(71) Applicant: SIGNIFY HOLDING B.V., EINDHOVEN (NL)

(72) Inventor: WILLEM DIRK VAN DRIEL, 's-Hertogenbosch (NL)

(21) Appl. No.: 18/863,358

(22) PCT Filed: Jun. 16, 2023
(86) PCT No.: PCT/EP2023/066316

§ 371 Date: Nov. 6, 2024

(30) Foreign Application Priority Data
Jun. 23, 2022 (EP) 22180617.7

(51) Int. Cl. F21V 14/02; F21Y 105/10; F21Y 113/17; F21Y 115/10

(52) U.S. Cl. CPC F21V 14/02; F21Y 2105/10; F21Y 2113/17; F21Y 2115/10

(57) ABSTRACT

The invention provides a light generating system (1000) comprising a plurality of first light generating devices (110), a flexible substrate (30), a first light-responsive material (1040), a second light generating device (120), and a control system (300); wherein the first light-responsive material (1040) comprises a first liquid-crystalline elastomer (1041); wherein the first light-responsive material (1040) is responsive to radiation having a second wavelength (k2) such that the first light-responsive material (1040) under radiation having the second wavelength (λ2) at least temporarily expands or shrinks.

### FIELD OF THE INVENTION

The invention relates to a lighting device comprising a light generating system.

### BACKGROUND OF THE INVENTION

Film forming photosensitive materials are known in the art. For instance, WO2006117403A1, describes a self-supporting or substrate-supported film or layer of a photosensitive material comprising a water insoluble complex having photosensitive tectonic units, wherein the photosensitive part may undergo a photoreaction, selected from photoisomerizations, photocycloadditions and photoinduced rearrangements.

US2019/213978A1 discloses a flexible display device that includes a base substrate, a display component located on the base substrate, a top-layer cover plate configured to package the display component, a deformation layer configured to create a deformation to drive the flexible display device to deform, and a control element located on the base substrate and configured to control a deformation variable of the deformation layer.

U.S. Pat. No. 11,170,679B discloses a time division display control method disclosed comprising displaying a first image by a display device, and changing display pixel distribution of the display device at least once within a preset permitted staying duration of vision of human eyes and displaying the first image by the display device changed each time, to cause the displayed first images to be displayed in human eyes as a second image in an overlapped manner. Utilization of display pixels of a display device and display quality of at least a local part of an image can be improved, thereby better meeting diversified actual application demands of users.

### SUMMARY OF THE INVENTION

Light generating devices, especially LED-based devices, are interesting for various applications including spots, stage-lighting, headlamps, home and office lighting, and (fluorescence) microscopy and endoscopy etc. However, optics used in current LED-based products are static items as they are fixed in space. For application in, for example, microrobots and biotechnology, such as for the use as artificial muscles, it may be desired to use dynamic LED-based products.

Hence, it is an aspect of the invention to provide an alternative lighting device, which preferably further at least partly obviates one or more of above-described drawbacks. The present invention may have as object to overcome or ameliorate at least one of the disadvantages of the prior art, or to provide a useful alternative.

It is herein proposed to use a stimulus responsive materials. Stimulus responsive materials are materials that may change their shape, size, or appearance under the influence of a stimulus, such as temperature, light or pH. The properties can be adjusted depending on the needs of the user or by environmental changes. Using pH as a stimulus may bring the drawback of having to change the immediate chemical environment of a stimulus responsive polymer film. A temperature responsive polymer film may require the integration of complex electrodes or heating elements, which may increase the complexity and cost of assembly. It appears however, that light stimulated stimulus responsive materials may be an interesting option. An appealing stimulus for these polymers is light, as it can be applied locally in a non-contact fashion. Especially, it seems useful to apply liquid-crystalline elastomers. Liquid-crystalline elastomers (LCEs) appear to be able to perform a reversible shape-change in response to an external light stimulus. LCEs are considered ‘smart’ materials as they can be designed to react to predetermined stimuli only, while not reacting to other stimuli. The material characteristics open ideas of possible applications in lighting. By using LCE materials it may be possible to make optics dynamic items. Hence, the invention proposes to use a light-responsive material to provide dynamic properties of a light generating system.

According to a first aspect, the invention provides a lighting device comprising a light generating system (“system”), the light generating system comprising a plurality of first light generating devices, a flexible substrate (or “substrate”), a first light-responsive material, a second light generating device, and a control system. Especially, in embodiments, the plurality of first light generating devices may comprise one or more solid state light sources. More especially, the plurality of first light generating devices may, in embodiments, be configured to generate first device light. Further, in embodiments, the flexible substrate may be configured to support the plurality of first light generating devices. In embodiments, the first light-responsive material may comprise a first liquid-crystalline elastomer. Further, in embodiments, the first light-responsive material may be responsive to radiation having a second wavelength 22, such that the first light-responsive material under radiation having the second wavelength 22 may at least temporarily expand or shrink. Yet further, in embodiments, the first light-responsive material may be arranged in contact with the flexible substrate such that an expansion or shrinkage of the first light-responsive material may lead to a conformational change of the flexible substrate. In embodiments, the second light generating device may be configured to generate second device light having a second spectral power distribution including intensity at the second wavelength 22. Especially, in embodiments, the first light-responsive material may be configured in a light-receiving relationship with the second light generating device. Further, in embodiments, the light generating system may be configured to generate system light. Yet further, in embodiments, the system light may comprise at least part of the first device light. In embodiments, the control system may be configured to control one or more of a beam shape and a beam direction of a beam of system light by controlling the second light generating device. Furthermore, in embodiments, the first device light may not provide a stimulus to the first light-responsive material. Additionally or alternatively, the one or more solid state light sources may comprise LED dies with a cross-sectional area of ≤1 mm². In specific embodiments, the invention provides a light generating system comprising a plurality of light generating devices, a flexible substrate, a first light-responsive material, a second light generating device, and a control system; wherein: the one or more first light generating devices may comprise one or more solid state light sources; wherein the plurality of first light generating devices may be configured to generate first device light; wherein the flexible substrate may be configured to support the plurality of first light generating devices; wherein the first light-responsive material may comprise a first liquid-crystalline elastomer; wherein the first light-responsive material may be responsive to radiation having a second wavelength λ2, such that the first light-responsive material under radiation having the second wavelength λ2 may at least temporarily expand or shrink; wherein the first light-responsive material may be arranged in contact with the flexible substrate such that an expansion or shrinkage of the first light responsive material may lead to a conformational change of the flexible substrate; wherein the second light generating device may be configured to generate second device light having a second spectral power distribution including intensity at the second wavelength λ2; wherein the first light-responsive material may be configured in a light-receiving relationship with the second light generating device; and wherein the light generating system may be configured to generate system light comprising at least part of the first device light; wherein the control system may be configured to control one or more of a beam shape and beam direction of a beam of system light by controlling the second light generating device.

With the present lighting device, it may be possible to prepare a dynamic lighting device comprising a light generating system, i.e. a light generating system that may expand, shrink, bend, or fold. The present system may enable the use of user-friendly light-responsive materials for the purpose of making a dynamic light generating system. Through the use of solid state light sources, such as μLEDs, the present system may be more compact, it may employ user-friendly light intensities and it may have improved durability. Additionally or alternatively, through the use of solid state light sources the present system may provide higher light intensities, improved light efficiency and improved optical flexibility. Hence, amongst others, the invention provides an optical contractile unit LCE with μLEDs.

As indicated above, in embodiments, the light generating system may comprise a plurality of first light generating devices, a flexible substrate, a first light-responsive material, a second light generating device, and a control system. Here below, first some general embodiments of the system are described, followed by some more specific embodiments.

A light generating device may especially be configured to generate device light. Especially, the light generating device may comprise a light source. The light source may especially be configured to generate light source light. In embodiments, the device light may essentially consist of the light source light. In other embodiments, the device light may essentially consist of converted light source light. In yet other embodiments, the device light may comprise (unconverted) light source light and converted light source light. Light source light may be converted with a luminescent material into luminescent material light and/or with an upconverter into upconverted light (see also below). The term “light generating device” may also refer to a plurality of light generating devices which may provide device light having essentially the same spectral power distributions. In specific embodiments, the term “light generating device” may also refer to a plurality of light generating devices which may provide device light having different spectral power distributions.

The term “light source” may in principle relate to any light source known in the art. It may be a conventional (tungsten) light bulb, a low pressure mercury lamp, a high pressure mercury lamp, a fluorescent lamp, an LED (light emissive diode). In specific embodiments, the light source comprises a solid state LED light source (such as an LED or laser diode (or “diode laser”)). The term “light source” may also relate to a plurality of light sources, such as 2-2000 (solid state) LED light sources. Hence, the term LED may also refer to a plurality of LEDs.

Further, the term “light source” may in embodiments also refer to a so-called chips-on-board (COB) light source. The term “COB” especially refers to LED chips in the form of a semiconductor chip that is neither encased nor connected but directly mounted onto a substrate, such as a PCB. Hence, a plurality of light emitting semiconductor light sources may be configured on the same substrate. In embodiments, a COB is a multi LED chip configured together as a single lighting module.

The term “light source” may also refer to a chip scaled package (CSP). A CSP may comprise a single solid state die with provided thereon a luminescent material comprising layer. The term “light source” may also refer to a midpower package. A midpower package may comprise one or more solid state die(s). The die(s) may be covered by a luminescent material comprising layer. The die dimensions may be equal to or smaller than 1 mm, such as in the range of e.g. 0.2-1 mm. Hence, in embodiments the light source comprises a solid state light source. Further, in specific embodiments, the light source comprises a chip scale packaged LED. Herein, the term “light source” may also especially refer to a small solid state light source, such as having a mini size or micro size. For instance, the light sources may comprise one or more of mini LEDs and micro LEDs. Especially, in embodiments the light sources may comprise micro LEDs or “microLEDs” or “μLEDs”. Herein, the term mini size or mini LED especially indicates solid state light sources having dimensions, such as die dimensions, especially length and width, selected from the range of 100 μm-1 mm. Herein, the term u size or micro LED especially indicates solid state light sources having dimensions, such as die dimensions, especially length and width, selected from the range of 100 μm and smaller. In specific embodiments, the solid state light sources may comprise LED dies with a cross-sectional area of ≤1.5 mm², such as a cross-sectional area of ≤1 mm², like a cross-sectional area of ≤0.8 mm². In embodiments, the solid state light sources may comprise LED dies with a cross-sectional area of at least 100 μm², such as especially at least about 200 μm², such at least about 400 μm².

The light source may have a light escape surface. Referring to conventional light sources such as light bulbs or fluorescent lamps, it may be an outer surface of a glass or a quartz envelope. For LED's it may for instance be the LED die, or when a resin is applied to the LED die, the outer surface of the resin. In principle, it may also be the terminal end of a fiber. The term escape surface especially relates to that part of the light source, where the light actually leaves or escapes from the light source. The light source is configured to provide a beam of light. This beam of light (thus) escapes from the light exit surface of the light source.

Likewise, a light generating device may comprise a light escape surface, such as an end window. Further, likewise a light generating system may comprise a light escape surface, such as an end window.

The term “light source” may refer to a semiconductor light-emitting device, such as a light emitting diode (LEDs), a resonant cavity light emitting diode (RCLED), a vertical cavity laser diode (VCSELs), an edge emitting laser, etc. . . . The term “light source” may also refer to an organic light-emitting diode (OLED), such as a passive-matrix (PMOLED) or an active-matrix (AMOLED). In specific embodiments, the light source comprises a solid-state light source (such as an LED or laser diode). In embodiments, the light source comprises an LED (light emitting diode). The terms “light source” or “solid state light source” may also refer to a superluminescent diode (SLED).

The term LED may also refer to a plurality of LEDs.

The term “light source” may also relate to a plurality of (essentially identical (or different)) light sources, such as 2-2000 solid state light sources. In embodiments, the light source may comprise one or more micro-optical elements (array of micro lenses) downstream of a single solid-state light source, such as an LED, or downstream of a plurality of solid-state light sources (i.e. e.g. shared by multiple LEDs). In embodiments, the light source may comprise an LED with on-chip optics. In embodiments, the light source comprises pixelated single LEDs (with or without optics) (offering in embodiments on-chip beam steering).

In embodiments, the light source may be configured to provide primary radiation, which is used as such, such as e.g. a blue light source, like a blue LED, or a green light source, such as a green LED, and a red light source, such as a red LED. Such LEDs, which may not comprise a luminescent material (“phosphor”) may be indicated as direct color LEDs.

In other embodiments, however, the light source may be configured to provide primary radiation and part of the primary radiation is converted into secondary radiation. Secondary radiation may be based on conversion by a luminescent material. The secondary radiation may therefore also be indicated as luminescent material radiation. The luminescent material may in embodiments be comprised by the light source, such as an LED with a luminescent material layer or dome comprising luminescent material. Such LEDs may be indicated as phosphor converted LEDs or PC LEDs (phosphor converted LEDs). In other embodiments, the luminescent material may be configured at some distance (“remote”) from the light source, such as an LED with a luminescent material layer not in physical contact with a die of the LED. Hence, in specific embodiments the light source may be a light source that during operation emits at least light at wavelength selected from the range of 380-470 nm. However, other wavelengths may also be possible. This light may partially be used by the luminescent material.

In embodiments, the light generating device may comprise a luminescent material. In embodiments, the light generating device may comprise a PC LED. In other embodiments, the light generating device may comprise a direct LED (i.e. no phosphor). In embodiments, the light generating device may comprise a laser device, like a laser diode. In embodiments, the light generating device may comprise a superluminescent diode. Hence, in specific embodiments, the light source may be selected from the group of laser diodes and superluminescent diodes. In other embodiments, the light source may comprise an LED.

The light source may especially be configured to generate light source light having an optical axis (O), (a beam shape) and a spectral power distribution. The light source light may in embodiments comprise one or more bands, having band widths as known for lasers.

The term “light source” may (thus) refer to a light generating element as such, like e.g. a solid state light source, or e.g. to a package of the light generating element, such as a solid state light source, and one or more of a luminescent material comprising element and (other) optics, like a lens, a collimator. A light converter element (“converter element” or “converter”) may comprise a luminescent material comprising element. For instance, a solid state light source as such, like a blue LED, is a light source. A combination of a solid state light source (as light generating element) and a light converter element, such as a blue LED and a light converter element, optically coupled to the solid state light source, may also be a light source (but may also be indicated as light generating device). Hence, a white LED is a light source (but may e.g. also be indicated as (white) light generating device).

The term “light source” herein may also refer to a light source comprising a solid state light source, such as an LED or a laser diode or a superluminescent diode.

The term “light source” may (thus) in embodiments also refer to a light source that is (also) based on conversion of light, such as a light source in combination with a luminescent converter material. Hence, the term “light source” may also refer to a combination of an LED with a luminescent material configured to convert at least part of the LED radiation, or to a combination of a (diode) laser with a luminescent material configured to convert at least part of the (diode) laser radiation.

In embodiments, the term “light source” may also refer to a combination of a light source, like an LED, and an optical filter, which may change the spectral power distribution of the light generated by the light source. Especially, the term “light generating device” may be used to address a light source and further (optical components), like an optical filter and/or a beam shaping element, etc.

The phrases “different light sources” or “a plurality of different light sources”, and similar phrases, may in embodiments refer to a plurality of solid-state light sources selected from at least two different bins. Likewise, the phrases “identical light sources” or “a plurality of same light sources”, and similar phrases, may in embodiments refer to a plurality of solid-state light sources selected from the same bin.

The term “solid state light source”, or “solid state material light source”, and similar terms, may especially refer to semiconductor light sources, such as a light emitting diode (LED), a diode laser, or a superluminescent diode.

Hence, especially the plurality of first light generating devices may comprise one or more light sources. More especially, the one or more light sources may, in embodiments, comprise one or more solid state light sources. Especially, the one or more light sources may be configured to generate first light source light. The solid state light sources may be LEDs, such as microLEDs or miniLEDs (see also above and further below).

Further, in embodiments, the light generating system may comprise a flexible substrate. The flexible substrate may, in embodiments, be configured to support the plurality of first light generating devices. The flexible substrate may be a substrate having elastic properties. Further, in embodiments, the flexible substrate may comprise a material selected from the group comprising, a metal, a polymeric material, a glass, a paper, a 3D printed material, or a combination thereof. The material may be selected such, that the flexible substrate may be able to at least temporarily bend, expand, shrink or move in another fashion along with the first light-responsive material. Hence, the flexible substrate may comprise a material that may allow for a conformational change of the flexible substrate to occur. Especially, the flexible substrate may comprise a polymeric material. For example, in embodiments, the flexible substrate may comprise a polyamide foil. In another example, the flexible substrate may comprise a polyethylene terephthalate (PET) foil. In yet other embodiments, the flexible substrate may comprise a silicone foil. Additionally or alternatively, the flexible substrate may comprise a LED strip or may be comprised by a LED strip (as support for the LEDs). However, the flexible substrate may also have other forms, i.e., the flexible substrate may be shaped as a sheet or in a 3D shape, such as a sphere. For example, in specific embodiments, the flexible substrate may comprise a metal carrier sheet. Furthermore, the flexible substrate may have a backside and a frontside (see also further below). The backside and the frontside may be separated by a height h1. In embodiments, the height h1 may be selected from the range of 20 μm-100 mm, such as from the range of 50 μm-10 mm. For instance, in embodiments the height h1 may be selected from the range of 5 mm and smaller, such as 2 mm and smaller, like up to maximum 1 mm. In embodiments the height h1 may be selected from the range at least about 40 μm, such as at least about 50 μm, such as at least about 80 μm.

In embodiments, the first light-responsive material may comprise a first liquid-crystalline elastomer. As will also be further elucidated below, in embodiments the light generating system may also comprise a second light-responsive material. The second light-responsive material may comprise a second liquid-crystalline elastomer (different from the liquid-crystalline elastomer). Though the first light-responsive material and the second light-responsive material may have different properties, they both are light-responsive materials. Hence, some embodiments of such materials are described below (in general).

Liquid crystalline elastomers (LCEs) may comprise (slightly) crosslinked liquid crystalline polymer networks. These networks may combine the entropic elasticity of an elastomer with the self-organization of the liquid crystalline phase. To produce light-responsive LCEs, photochromic dyes can be embedded in a polymer matrix. In embodiments, the first (and/or second) liquid-crystalline elastomer may comprise a liquid crystal mesogen, a cross-linker and a photochromic dye. The cross-linker may, in embodiments, be a polysiloxane. Further, in embodiments, the photochromic dye may be a dye selected from a group comprising spiropyrans, spirooxazines, photochromic quinones, diarylethenes and azobenzenes. In specific embodiments the first (and/or second) liquid-crystalline elastomer may comprise at least a mesogenic monomer which acts as the liquid crystal, a mesogenic monomer which acts as the cross-linker, and an azobenzene photochromic dye. Especially, in specific embodiments, the first (and/or second) liquid-crystalline elastomer may comprise 4-methoxybenzoic acid 4-(6-acryloyloxyhexyloxy)phenyl ester, 1,4-Bis[4-(3-acryloyloxypropyloxy)benzoyloxy]-2-methylbenzene, and 6-[{4-[(E)-(2-cyano-4-nitrophenyl)diazenyl]phenyl}(ethyl)amino]hexyl acrylate. Further, in embodiments, the first (and/or second) liquid-crystalline elastomer may comprise 5-20 mol % cross-linker, like 7.5-15 mol % cross-linker, such as 9-12 mol % cross-linker. Furthermore, in embodiments, the first (and/or second) liquid-crystalline elastomer may comprise 80-95 mol % mesogenic monomer, like 85-93 mol % mesogenic monomer, such as 88-91 mol % mesogenic monomer. Yet further, the first (and/or second) liquid-crystalline elastomer may, in embodiments, comprise 0.1-1.5 mol % photochromic dye, like 0.5-1.3 mol % photochromic dye, such as 0.8-1.1 mol % photochromic dye. Additionally or alternatively, in embodiments, a curing agent for photoinitiation may be added. Especially, in embodiments, about 0.5-1.5 mol % of curing agent may be added, such as about 0.8-1.2 mol % of curing agent. The curing agent may, for example, be Irgacure 369. However, suitable alternatives are known in the art and may be selected by the person skilled in the art.

Further, in embodiments, the first light-responsive material may be responsive to radiation having a second wavelength λ2, such that the first light-responsive material under radiation having the second wavelength λ2 may at least temporarily expand or shrink. Under such radiation, first a stretching stage and then a steady state stage may occur. Thus, radiation having a second wavelength λ2 may evoke a response from the first light-responsive material. Such response may also, in other embodiments, be a change in shape, size, color or general appearance. In specific embodiments, radiation having a second wavelength λ2 may be absorbed by the light-responsive material and may be converted into mechanical energy. The mechanical energy may produce stress, which may lead to expansion or shrinkage. In embodiments, the radiation may have a second wavelength λ2 selected from the range of 380-780 nm, such as 380-700 nm, such as from the range of 400-650 nm, like from the range of 500-550 nm. However, in other embodiments the radiation may have a second wavelength in the UV or infrared.

Yet further, in embodiments, the first light-responsive material may be arranged in contact with the flexible substrate such that an expansion or shrinkage of the first light-responsive material may lead to a conformational change of the flexible substrate.

In embodiments, the first light-responsive material may be arranged in contact with the flexible substrate in between the plurality of light sources and the flexible substrate. In embodiments, the first light-responsive material may (thus) be arranged in contact with the flexible substrate at the same side as the side where the plurality of light sources are configured. Further, in embodiments, the first light-responsive material may be arranged in contact with the flexible substrate on the side facing away from the plurality of light sources.

Furthermore, in specific embodiments, expansion or shrinkage of the first light-responsive material may produce stress on the flexible substrate. Stress on the flexible substrate may lead to a conformational change of the flexible substrate. In embodiments, the conformational change may comprise bending, folding, wrinkling, stretching, and thinning of the flexible substrate (see also further below).

In embodiments, the second light generating device may comprise one or more (solid state) light sources (see also above and further below). Especially, the one or more light sources may be configured to generate second light source light. Furthermore, in embodiments, the second light generating device may be configured to generate second device light. The second device light may, in embodiments, comprise at least part of the second (solid state) light source light. The second light generating device may further, in embodiments, be configured to generate second device light having a second spectral power distribution including intensity at the second wavelength λ2. Especially, in embodiments, the first light-responsive material may be configured in a light-receiving relationship with the second light generating device. More especially, the second light generating device may, in embodiments, be configured to provide second device light having a spectral power distribution including intensity at the second wavelength λ2 onto the surface of the first light-responsive material, so as to provide an optical stimulus. The first light-responsive material may receive the stimulus provided by the second light generating device and may, in response, at least temporarily undergo expansion or shrinkage (see also above). Furthermore, in embodiments, the first device light may especially not provide a stimulus to the first light-responsive material. Especially, the first device light may not include intensity at the second wavelength λ2.

Hence, in embodiments there is essentially no spectral overlap between the first device light and the second device light.

The light generating system may, in embodiments, be configured to generate system light. The system light may comprise at least part of the first device light. Further, the system light may essentially not comprise second device light (or third device light (see below). Hence, device light used to control the light-responsive material(s) may essentially not be comprised by the system light. For instance, less than 5%, such as less than 1% of the spectral power of the system light may consist of device light used to control the light-responsive material(s). Yet, in embodiments at least 95% of the spectral power of the system light may consist of the first device light.

Due to irradiating or not irradiating the first light-responsive material with the second device light, the first light-responsive material will be in a shrunken state or in an expanded state under irradiation, and in an expanded state or shrunken state when not being illuminated with the second device light. In this way, the position of one or more light generating devices may be temporarily shifted. This may have impact on a beam of system light, as the beamlets of the first light generating devices may temporarily be shifted and/or be provided under a different angle, dependent upon the shrunken state or expanded state. Therefore, beam shape and/or beam direction of a beam of system light may be controlled (with the second device light).

In embodiments, the control system may be configured to control one or more of a beam shape and a beam direction of a beam of system light by controlling the second light generating device (and the optional third light generating device (see further below)).

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions form a remote control. In embodiments, the control system may be controlled via an App on a device, such as a portable device, like a Smartphone or I-phone, a tablet, etc., The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, which can only operate in a single operation mode (i.e. “on”, without further tunability).

In specific embodiments, the control system may control in dependence of one or more of an input signal of a user interface, a sensor signal (of a sensor), and a timer. The term “timer” may refer to a clock and/or a predetermined time scheme. A user may for example through the user interface instruct the control system to change the beam shape. The control system may as a result adapt an operational mode of the second device light accordingly and as such may cause a conformational change in the first (and/or) second light responsive material resulting in a change in beam shape. Likewise, a user may also (through the user interface) instruct the control system to change the beam direction. Furthermore, in embodiments, the control system may respond to a sensor signal, e.g. a sensor signal generated when an individual passes by a sensor of the control system. Hence, in embodiments, the control system may comprise a sensor that may send a signal as a response of an individual passing by. This signal may for example cause the control system to control the turning on or off of the second light generating device. In another example the control system may be configured to control the operational mode of the second light generating device based on a timer, e.g. the control system may turn on the second light generating device for a set time period, or the control system may turn off the second light generating device at a set sleep time.

Here below, some further embodiments are described.

In embodiments, the light generating system may provide the first device light. Especially, the first device light may have a first spectral power distribution having essentially no intensity at the second wavelength λ2, i.e. less than 0.1% of its spectral power. Therefore, in embodiments the first light generating device and the first light-responsive material (and the optional second light-responsive material) may be selected and configured such, that the first light-responsive material (and the optional second light-response material) do not respond to the first device light of the first light generating device.

First device light having a first spectral power distribution having no intensity at the second wavelength λ2 may be advantageous as it may allow the use of the light generating system without influence of the first device light on the controlling of the light responsive material(s).

As the system comprises multiple first light generating devices and a control system, it may be possible to control the multiple first light generating devices individually. In specific embodiments, it may be possible to control the multiple sets, of each at least a single first light generating device, individually. All first light generating devices may be configured to generate first device light having essentially the same spectral power distributions. In other embodiments, two or more first light generating devices are configured to generate first device light having different spectral power distributions. Hence, color points of first device light of two or more first light generating devices may differ.

In specific embodiments, colors or color points of a first type of light and a second type of light may be different when the respective color points of the first type of light and the second type of light differ with at least 0.01 for u′ and/or with at least 0.01 for v′, even more especially at least 0.02 for u′ and/or with at least 0.02 for v′. In yet more specific embodiments, the respective color points of first type of light and the second type of light may differ with at least 0.03 for u′ and/or with at least 0.03 for v′. Here, u′ and v′ are color coordinates of the light in the CIE 1976 UCS (uniform chromaticity scale) diagram.

In embodiments, two or more first light generating devices are configured to generate first device light having different colors. In (other) embodiments, two or more first light generating devices are configured to generate first device light having different correlated color temperatures, such as differing at least about 500 K.

In embodiments, it may be possible to operate the first light generating devices and the second light generating device simultaneously, which allows for a dynamic light generating system. In (other) embodiments, it may also be possible to operate only the first light generating devices without the second light generating device, which allows for a static light generating system.

In embodiments, the first light generating devices may generate first device light. Especially, in embodiments, the first device light may have a first spectral power distribution, having intensity in the visible wavelength range. Additionally or alternatively, the first spectral power distribution may have intensity outside of the visible wavelength range, such as in the UV or IR wavelength range. More especially, the first spectral power distribution may have no intensity at the second wavelength λ2, i.e. less than 0.1% of its spectral power, such as less than 0.05% of its spectral power, like less than 0.01% of its spectral power.

In embodiments, the light generating system may provide system light. As indicated above, the system light may in embodiments essentially consist of the first device light. The system light may, in embodiments, have a system light optical axis Os. The system light optical axis Os may be defined as an imaginary line that defines a path through the flexible substrate, and the light-responsive material of the light generating system, along which system light propagates through the system. Especially, the system light optical axis Os may coincide with the direction of the system light with the highest radiant flux.

Further, in embodiments, the second device light may have a second optical axis O2. Especially, the second optical axis O2 may be defined as an imaginary line that defines a path through the second light generating device, along which second device light propagates through the device. More especially, in embodiments, the second optical axis O2 may coincide with the direction of the second device light with the highest radiant flux.

Yet further, in embodiments, the system optical axis Os and the second optical axis O2 may have a first mutual angle α1. Especially, in embodiments, α1 may be selected from the range of 145-225°. With the present system, it may be possible to improve the light-receiving relationship between the first light-responsive material and the second light generating device. The described angle allows for optimization of the amount of spectral intensity that may be received by the first light-responsive material and thus optimization of the response of the first light-responsive material. More especially, the first mutual angle α1 may be selected from the range of 160-210°, like from the range of 170-190°. This may especially apply when the second light generating device is configured facing the frontside.

The flexible substrate may have a frontside and a backside. The frontside of the flexible substrate may be defined as the surface where the plurality of first light generating devices are arranged. Hence, the frontside may face in the same direction along which first device light propagates out of the plurality of first light generating devices. Therefore, the backside may be defined as the surface of the flexible substrate facing in the opposite direction of the direction along which first device light propagates from the plurality of first light generating devices.

In alternative embodiments, the flexible substrate may be transmissive for the second device light. For example, in embodiments, the second light generating device may be configured facing the backside of the flexible substrate and the first light-responsive material may be configured at the frontside of the flexible substrate. In such instance, the second device light may enter from the backside and pass through the transmissive flexible substrate.

Yet, in alternative embodiments, the second light generating device may be configured facing the frontside of the flexible substrate and the first light-responsive material may be configured at the backside of the flexible substrate, opposite of the frontside. Hence, in embodiments, the second device light may enter the frontside and pass through the transmissive flexible substrate.

As can be derived from the above, in embodiments, the system light optical axis Os may have a position and/or angle, which may be dependent on the first light-responsive material (or more especially whether or not the first light responsive material is irradiated with the second device light or not).

In embodiments, the light generating system may thus comprise a second light generating device. Especially, in embodiments, the second light generating device may be configured to generate second device light. Especially, in embodiments, the second light generating device may comprise a solid state light source. Further, the second device light may, in embodiments, have a radiant flux selected from the range of 15-60 mW/cm², relative to a surface of the first (and/or second) light-responsive material, such as selected from the range of 30-50 mW/cm², like from the range of 35-40 mW/cm². This range of the irradiance onto the light-responsive material may be beneficial to the flexibility of the system as it may help optimize the stress developed in the light-responsive material. An irradiance 35-40 mW/cm² of may generate stresses of up to 80 mN/mm² at 20-25° C.

Hence, in specific embodiments, the light generating system may comprise a second light generating device and a plurality of first light generating devices, wherein the second light generating device may comprise a solid state light source; and wherein the plurality of first light generating devices may be configured to generate first device light having intensity at one or more wavelengths in the visible wavelength range, including at a first wavelength λ1.

The second light generating device may comprise one or more light sources. The one or more light sources may, in embodiments, comprise solid state light sources (see also above). Especially, the one or more light sources may be configured to generate second light source light. Furthermore, in embodiments, the second light generating device may be configured to generate second device light. The second device light may, in embodiments, comprise at least part of the second light source light.

Furthermore, in embodiments, the plurality of first light generating devices may be configured to generate first device light. The first device light may, in embodiments, comprise at least part of the light source light. Furthermore, in embodiments, the first device light may have intensity at one or more wavelengths in the visible wavelength range, including at a first wavelength λ1. Especially, in embodiments, the first device light may have intensity at one or more wavelengths selected from the range of 380-780 nm, such as 380-700 nm. In embodiments, the first device light may be white light. In specific embodiments, at least 80%, such as at least about 90% of the spectral power of the first device light may be in the visible wavelength range of 380-780 nm. However, other embodiments may also be possible.

As indicated above, the system light may comprise at least part of the first device light. In specific embodiments, the system light may essentially consist of the first device light. Hence, in specific embodiments the system light may be white light.

The term “white light” herein, is known to the person skilled in the art. It especially relates to light having a correlated color temperature (CCT) between about 1800 K and 20000 K, such as between 2000 and 20000 K, especially 2700-20000 K, for general lighting especially in the range of about 2700 K and 6500 K. In embodiments, e.g. for backlighting purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL. Especially, in embodiments, the system light may be warm white light. Additionally or alternatively, in embodiments, the system light may be cool white light. Furthermore, in embodiments the system light may have a correlated color temperature selected from the range of 1800-20000 K, such as from the range of 5000-20000, like from the range of 1800-12000 K. Additionally or alternatively, the system light may have a color rendering index selected from the range of ≥70, such as from the range of ≥80, like from the range of ≥85. However, the system light may also be colored light (see further also below).

As indicated above, the light generating system may comprise a flexible substrate. Especially, in embodiments, the flexible substrate may comprise a flexible printed circuit board (PCB). In embodiments, the flexible substrate may comprise a flexible board or a semi-rigid board having elastic properties, especially a flexible board. In other embodiments, the flexible substrate may be a flexible PCB.

With the present system, it may be possible to provide a light generating system with a low cost of production as PCBs are available at low cost. Another advantage provided by the use of a PCB as a flexible support may be that a PCB may be available through electronics 3D printing.

Here below, some more specific embodiments of the system are described.

In embodiments, the plurality of first light generating devices may at least partly be embedded in the first light-responsive material. Embedding the plurality of first light generating devices in the first light-responsive material may provide the benefit of improved stability of the system. The plurality of first light generating devices may be attached in a more secure manner when being embedded in the first light-responsive material. An additional advantage of embedding the plurality of first light generating devices in the first light-responsive material may be the increased compactness of the light generating system.

In embodiments, the light emitting surfaces of the first light generating devices may not be embedded in the first light-responsive material. In further embodiments, the first light-responsive material may be light transmissive for the first device light. In such embodiments, the first light generating devices may be fully embedded in the first light-responsive material. In yet further embodiments, the first light generating devices may not be embedded in the first light-responsive material.

In embodiments, the light generating system may comprise a first light-responsive material. Especially, in embodiments, the first light-responsive material may comprise (a) one or more of a polycarbonate, a poly(methyl methacrylate) (PMMA), a glass, (b) a liquid-crystalline elastomer and optionally (c) a hydrogel. Thus, in specific embodiments, the light generating system may comprise a first light-responsive material, wherein the first light-responsive material may comprise (i) one or more of a polycarbonate (PC), a poly(methyl methacrylate) (PMMA), a glass, (b) a liquid-crystalline elastomer (LCE) and (c) a hydrogel.

Especially, in embodiments, the plurality of first light generating devices may be configured in an array. More especially, the plurality of first light generating devices may be configured in an array of solid state light sources. Configuring the solid state light sources in an array may provide the advantage of facile (uniform) distribution of light over the area of the flexible substrate. Another advantage of configuring the solid state light sources in an array may be the simplification of the assembly process. Using an array of solid state light sources may eliminate the need to place individual solid state light sources onto the flexible substrate.

The array may be regular, random, or quasi random. Especially, in embodiments the array of first light generating devices may be a regular 2D array. However, other arrays, like a phyllotaxis tessellation or a sunflower tessellation, may also be possible. Especially, the array may be a regular array. In embodiments, the array may be an n*m array, wherein n and m are each individually selected from the range of at least 2. In specific embodiments, n and m are each individually selected from the range of 2-5. Hence, in embodiments there may be one or two constant pitches. The term “tessellation” may herein especially refer to a pattern of (repeated) shapes, especially polygons, that fit together closely without gaps or overlapping. In yet other embodiments, the array may be an irregular 2D array.

As indicated above, the plurality of first light generating devices may comprise solid state light sources. Further, the solid state light sources may, in embodiments, be LEDs, such as micro LEDs or mini LEDs. Especially, in embodiments, the solid state light sources maybe configured in an array.

In embodiments, the light generating system may comprise a flexible substrate. Especially, in embodiments, the flexible substrate in dependence of the second device light may comprise at least a first conformation wherein the flexible substrate may have a first radius r1. Further, the flexible substrate in dependence of the second device light may comprise at least a second conformation wherein the flexible substrate may have a second radius r2. Yet further, in embodiments, r1/r2≥1.1 or r1/r2≤0.9.

When the flexible substrate is essentially planar, the radius r1=∞ or the radius r2=∞. Hence, in specific embodiments, the first radius r1 may be infinite, i.e. the first conformation of the flexible substrate may be planar. In another specific embodiment, the second radius r2 may be infinite, i.e. the second conformation of the flexible substrate may be planar. In yet another specific embodiments, the first radius r1 and the second radius r2 may both be finite, i.e. the first conformation of the flexible substrate and the second conformation of the flexible substrate may both be nonplanar.

With the present system, it may be possible to provide a dynamic light generating system. An additional advantage may be that present system may be programmed to switch between multiple different scenes with different conformations of the flexible substrate.

The flexible substrate may comprise a material that may allow for a conformational change of the flexible substrate to occur. In embodiments, first light-responsive material may be arranged in contact with the flexible substrate such that an expansion or shrinkage of the first light-responsive material may lead to a conformational change of the flexible substrate. In specific embodiments, expansion or shrinkage of the first light-responsive material may produce stress in the flexible substrate, which may lead to the conformational change of the flexible substrate. The conformational change may, in embodiments, be bending of the flexible substrate into a convex or concave conformation. Hence, the conformational change may also be a bending of a flexible substrate from a convex or concave conformation into a less convex or less concave conformation, of even a full stretching into an essentially planar conformation.

In embodiments, the light generating system may comprise an optical component. Especially, in embodiments, the optical component may be configured downstream of the plurality of first light generating devices. The optical component may be configured to change one or more of the shape and size of the beam of system light.

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

In embodiments, the optical component may be selected from a lens, a reflector, a collimator, and a lightguide. The term “optics” may especially refer to (one or more) optical components. Hence, the terms “optics” and “optical components” may refer to the same items. The optics may include one or more of lenses, reflectors, collimators, lightguides, mirrors, prisms, diffusers, phase plates, polarizers, diffractive elements, gratings, dichroics, arrays of one or more of the afore-mentioned, etc. Alternatively or additionally, the term “optics” may refer to a holographic element or a mixing rod. In embodiments, the optics may include one or more of beam expander optics and zoom lens optics. See further above for examples of optics. In embodiments, the optics may comprise an integrator, like a “Koehler integrator” (or “Köhler integrator”).

Especially, in embodiments, at least one of the plurality of first light generating devices may be configured to provide the first device light with a first optical axis Od1. The first optical axis Od1 may be defined as an imaginary line that defines a path through the first light generating device, along which system light propagates through the system. Especially, the first optical axis Od1 may coincide with the direction of the first device light with the highest radiant flux. Further, the optical component may, in embodiments have an optical component optical axis Oc1. Yet further, in embodiments, the control system may be configured to control one or more of (i) a second mutual angle α2 of the first optical axis Od1 and the optical component optical axis Oc1, and (ii) a first distance d1 between the first optical axis Od1 and the optical component optical axis Oc1, by controlling the second light generating device. Thus, in specific embodiments, the light generating system may comprise a plurality of first light generating devices, wherein at least one of the plurality of first light generating devices may be configured to provide the first device light with a first optical axis Od1, wherein the optical component may have an optical component optical axis Oc1, wherein the control system may be configured to control one or more of (i) a second mutual angle α2 of the first optical axis Od1 and the optical component optical axis Oc1, and (ii) a first distance d1 between the first optical axis Od1 and the optical component optical axis Oc1, by controlling the second light generating device. Hence, with the present system, it may be possible to tailor the beam size, the beam direction and the beam intensity of the light beam generated by the system.

Especially, in embodiments, the first optical axis Od1 and the optical component optical axis Oc1 may intersect, creating a mutual angle α2. The mutual angle α2 may be an angle selected from the range of 0-180°, such as from the range of 0-90°, like from the range of 0-45°, especially from the range of 5-45°. In specific embodiments, the first optical axis Od1 and the optical component optical axis Oc1 may coincide, i.e. the mutual angle α2 may be 0°.

In embodiments, the first optical axis Od1 and the optical component optical axis Oc1 may be separated by a first distance d1. In specific embodiments, the first distance d1 between the first optical axis Od1 and the optical component optical axis Oc1 may be zero, i.e. the first optical axis Od1 and the optical component optical axis Oc1 may coincide.

In embodiments, stretching and shrinking may lead to a length difference selected from the range of 1-150 μm, such as especially about 1-100 μm, such as 1-50 μm, especially 25-50 μm. Hence, a change in first distance may in embodiments be at maximum about 100 μm.

Further, in embodiment, the first optical axis Od1 and the optical component optical axis Oc1 may simultaneously have a non-zero mutual angle α2 and a non-zero first distance d1.

In specific embodiments, the flexible substrate may be fixed on one end, such that a conformational change of the flexible substrate may result in expansion or shrinkage in one direction.

Further, in embodiments, the control system may be configured to control one or more of the second mutual angle α2 of the first optical axis Od1 and the optical component optical axis Oc1, and the first distance d1 between the first optical axis Od1 and the optical component optical axis Oc1, by controlling the second light generating device. For example, in a first operational mode, the control system may be configured to control the second device such, that the second device light may cause the first light-responsive material to adopt a relaxed conformation. In this relaxed conformation, in embodiments, the mutual angle α2 may be 0° and the first distance d1 may be non-zero. In a second operational mode, the control system may be configured to control the second device such, that the second device light may cause the first light-responsive material to adopt an expanded conformation, due to the generated stress. In this expanded conformation, in embodiments, the mutual angle α2 may be 0° and the first distance d1 may be zero. Hence, the first optical axis Od1 and the optical component optical axis Oc1 may coincide. It may be clear to the person skilled in the art that other variations may be possible with regards to operational modes, the mutual angle α2, and the first distance d1.

In embodiments, the light generating system may further comprise a third light generating device and a second light-responsive material. Essentially all embodiments related to the second light generating device may also apply for the third light generating device, such as position, angle, etc. Further, essentially all embodiments related to the first light-response material may also apply to the second light-responsive material. Nevertheless, especially the effect on the substrate change may be different for the combination of second light generating device and first light-response material on the one hand and the combination of third light generating device and second light-response material on the other hand. Below, some embodiments are further described.

Especially, in embodiments, the second light-responsive material may comprise a second liquid-crystalline elastomer. Further, in embodiments, the second light-responsive material may be responsive to radiation having a third wavelength λ3 such that the second light-responsive material under radiation having the third wavelength λ3 may at least temporarily expand or shrink. Yet further, in embodiments, the second light-responsive material may be arranged in contact with the flexible substrate or in contact with the first light-responsive material, such that an expansion or shrinkage of the second light-responsive material may lead to a conformational change of the flexible substrate. Especially, in embodiments, the second wavelength may not be equal to the third wavelength, i.e. 12 #23. Further, in embodiments, the first light-responsive material and the second light-responsive material may have light responsiveness that may differ in direction. Furthermore, the third light generating device may, in embodiments, be configured to generate third device light. Especially, in embodiments, the third light generating device may comprise a solid state light source. Further, the third device light may, in embodiments, have a radiant flux selected from the range of 15-60 mW/cm², relative to a surface of the second (and/or first) light-responsive material, such as selected from the range of 30-50 mW/cm², like from the range of 35-40 mW/cm². More especially, in embodiments, the third device light may have a third spectral power distribution including intensity at the third wavelength λ3. Further, in embodiments, the second light-responsive material may be configured in a light-receiving relationship with the third light generating device. Yet further, the control system may, in embodiments, be configured to control one or more of a beam shape and beam direction of a beam of system light, by controlling the second light generating device and the third light generating device. Furthermore, in embodiments, the first device light may not provide a stimulus to the second light-responsive material. Yet further, in embodiments, the light generating system may provide the first device light. Especially, the first device light may have a first spectral power distribution having no intensity at the third wavelength λ3, i.e. less than 0.1% of its spectral power.

Thus, in specific embodiments, the light generating system may comprise a third light generating device and a second light-responsive material; wherein the second light-responsive material may comprise a second liquid-crystalline elastomer, wherein the second light-responsive material may be responsive to radiation having a third wavelength λ3 such that the second light-responsive material under radiation having the third wavelength λ3 may at least temporarily expand or shrink, wherein the second light-responsive material may be arranged in contact with the flexible substrate or in contact with the first light-responsive material, such that an expansion or shrinkage of the second light-responsive material may lead to a conformational change of the flexible substrate, wherein λ2≠λ3; wherein the first light-responsive material and the second light-responsive material may have light responsiveness that may differ in direction; wherein the third light generating device may be configured to generate third device light, wherein the third device light may have a third spectral power distribution including intensity at the third wavelength λ3; wherein the second light-responsive material may be configured in a light-receiving relationship with the third light generating device; and wherein the control system may be configured to control one or more of a beam shape and beam direction of a beam of system light, by controlling the second light generating device and the third light generating device.

With the present system, it may be possible to provide a dynamic light generating system, which may be responsive to multiple stimuli. As the light generating system may be responsive to multiple stimuli, it may also be dynamic in multiple directions or dimensions.

In embodiments, the second light-responsive material may be responsive to radiation having a third wavelength λ3, such that the second light-responsive material under radiation having the third wavelength λ3 may at least temporarily expand or shrink. Under such radiation, first a stretching stage and then a steady state stage may occur. Thus, radiation having a third wavelength λ3 may evoke a response from the second light-responsive material. Such response may also, in other embodiments, be a change in shape, size, color or general appearance. In specific embodiments, radiation having a third wavelength λ3 may be absorbed by the light-responsive material and may be converted into mechanical energy. The mechanical energy may produce stress, which may lead to expansion or shrinkage. In embodiments, the radiation may have a third wavelength λ3 selected from the range of 380-780 nm, such as 380-700 nm, such as from the range of 400-650 nm, like from the range of 500-550 nm. Especially, the third wavelength λ3 may be selected such, that λ2≠λ3. However, in other embodiments the radiation may have a third wavelength in the UV or infrared.

Yet further, in embodiments, the second light-responsive material may be arranged in contact with the flexible substrate such that an expansion or shrinkage of the second light-responsive material may lead to a conformational change of the flexible substrate. Especially, in embodiments, the second light-responsive material may be arranged in contact with the flexible substrate in between the plurality of light sources and the flexible substrate. Further, in embodiments, the second light-responsive material may be arranged in contact with the flexible substrate on the side facing away from the plurality of light sources. Additionally or alternatively, in embodiments, the second light-responsive material may be arranged in contact with the first light-responsive material such that an expansion or shrinkage of the second light-responsive material may lead to a conformational change of the flexible substrate. In specific embodiments, expansion or shrinkage of the second light-responsive material may produce stress on the flexible substrate. Stress on the flexible substrate may lead to a conformational change of the flexible substrate. In embodiments, the first light-responsive material and the second light-responsive material may be arranged on the same side of the flexible substrate. However, in other embodiments, the first light-responsive material and the second light-responsive material may be arranged on opposite sides of the flexible substrate. Additionally or alternatively, the first light-responsive material and the second light-responsive material may be arranged together in a mixed layer.

In embodiments, conformational change may comprise bending, folding, wrinkling, stretching, and thinning of the flexible substrate (see also further above and below).

The first light-responsive material and the second light-responsive material may, in embodiments, have light responsiveness that differ in direction. In embodiments, the first light-responsive material may have light responsiveness causing it to shrink, whereas the second light-responsive material may have light responsiveness causing it to expand, or vice versa. Additionally or alternatively, in embodiments, the first light-responsive material and the second light-responsive material may have light responsiveness causing a similar change, i.e. shrinking or expanding, but over non-parallel axes. In this way, it may e.g. be possible to make rotational movements.

In embodiments, the third light generating device may comprise one or more light sources (see also above and further below). Especially, the one or more light sources may be configured to generate third light source light. Furthermore, in embodiments, the third light generating device may be configured to generate third device light. The third device light may, in embodiments, comprise at least part of the third light source light. The third light generating device may further, in embodiments, be configured to generate third device light having a third spectral power distribution including intensity at the third wavelength λ3. Especially, in embodiments, the second light-responsive material may be configured in a light-receiving relationship with the third light generating device. More especially, the third light generating device may, in embodiments, be configured to provide third device light having a spectral power distribution including intensity at the third wavelength λ3 onto the surface of the second light-responsive material, so as to provide a stimulus. The second light-responsive material may receive the stimulus provided by the third light generating device and may, in response, at least temporarily undergo expansion or shrinkage (see also above). Furthermore, in embodiments, the first device light may especially not provide a stimulus to the first light-responsive material. Especially, the first device light may not include intensity at the second wavelength λ3.

Further, in embodiments, the control system may be configured to control one or more of a beam shape and a beam direction of a beam of system light by controlling the second light generating device and third light generating device (see also further above).

Yet further, in embodiments, the light generating system may provide the first device light. Especially, the first device light may have a first spectral power distribution having no intensity at the second wavelength λ3, i.e. less than 0.1% of its spectral power. Thus, in specific embodiments, the light generating system may provide the first device light, wherein the first device light may have a first spectral power distribution having no intensity at the second wavelength λ2 and no intensity at the third wavelength λ3, i.e. less than 0.1% of its spectral power. Especially, the first spectral power distribution may have no intensity at the second wavelength λ2, i.e. less than 0.1% of its spectral power, such as less than 0.05% of its spectral power, like less than 0.01% of its spectral power. More especially, the first spectral power distribution may have no intensity at the third wavelength λ3, i.e. less than 0.1% of its spectral power, such as less than 0.05% of its spectral power, like less than 0.01% of its spectral power.

In yet a further aspect, the invention also provides a lamp or a luminaire comprising the light generating system as defined herein. The luminaire may further comprise a housing, optical elements, louvres, etc, etc. . . . . The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. The lighting device is selected from the group of a lamp, a luminaire, a projector device, a disinfection device, a photochemical reactor, and an optical wireless communication device, comprising the light generating system as defined herein. The lighting device may comprise a housing or a carrier, configured to house or support, one or more elements of the light generating system. For instance, in embodiments the lighting device may comprise a housing or a carrier, configured to house or support one or more of light sources.

The invention also provides an arrangement of two or more lighting systems or of two or more lighting devices, such as a grid of lamps or luminaires. Such grid may be installed in a roof or ceiling. In embodiments, the lighting devices may be functionally connected to the control system. In embodiments, the lighting devices in the grid may comprise a sensor, especially one or more of a radiation sensor and an air flow sensor. In embodiments, the lighting devices may adjust its settings based on the one or more sensor signals of one or more lighting devices. In embodiments, the lighting devices, especially the control systems thereof, may communicate with one another. The lighting devices may comprise means for communicating with other units, systems or devices, such as on the basis of Bluetooth, WIFI, LiFi, ZigBee, BLE or WiMAX, or another wireless technology.

Instead of the terms “lighting device” or “lighting system”, and similar terms, also the terms “light generating device” or “light generating system”, and similar terms, may be applied. A lighting device or a lighting system may be configured to generate device light (or “lighting device light”) or system light (“or lighting system light”). As indicated above, the terms light and radiation may interchangeably be used.

The lighting device may comprise a light source. The device light may in embodiments comprise one or more of light source light and converted light source light (such as luminescent material light).

The lighting system may comprise a light source. The system light may in embodiments comprise one or more of light source light and converted light source light (such as luminescent material light).

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm. The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light.

The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, that can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1A-C and FIG. 2 schematically depict embodiments of the invention and some general aspects; and

FIG. 3 schematically depicts an embodiment of an application.

The schematic drawings are not necessarily to scale.

### DETAILED DESCRIPTION OF THE EMBODIMENTS

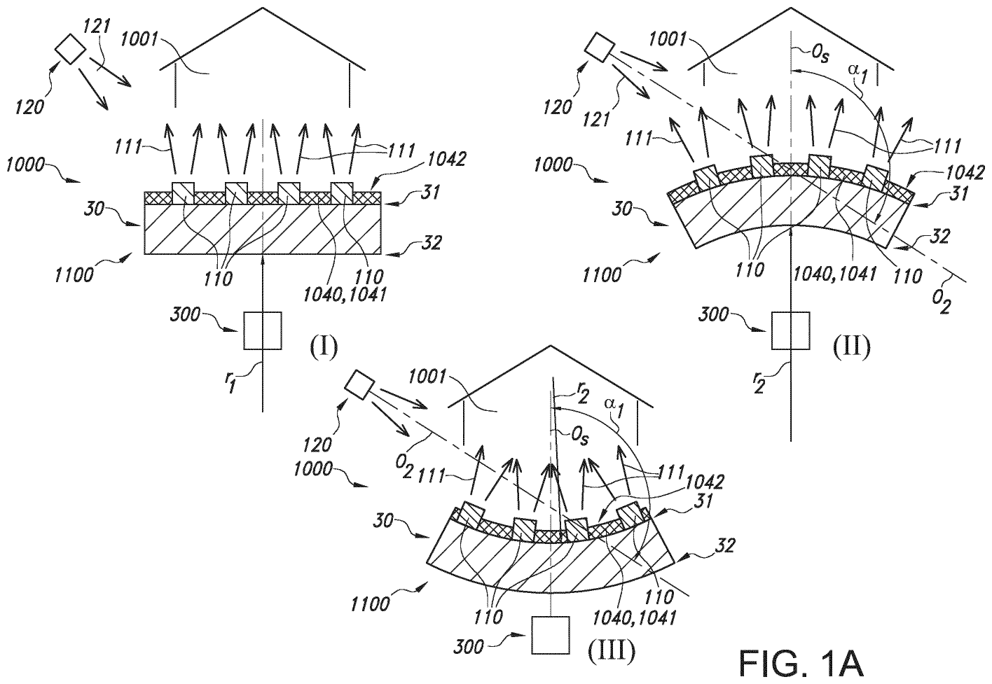

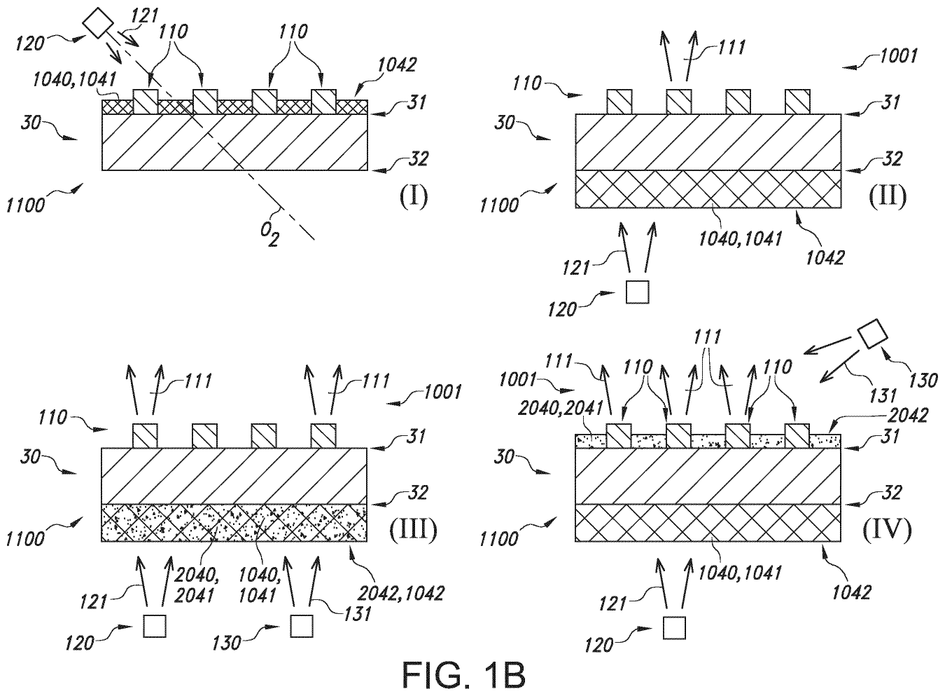

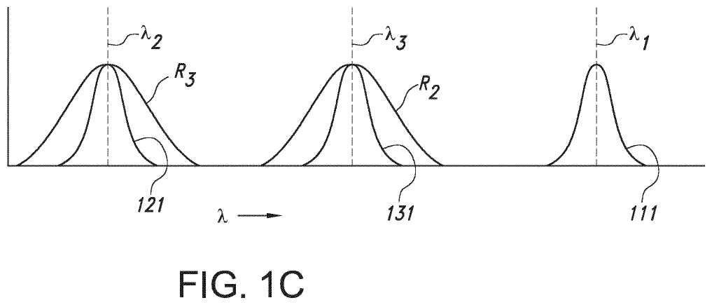

Referring to FIGS. 1A-1C, embodiments of the invention are schematically depicted. In embodiments, the invention may be a light generating system 1000 comprising a plurality of first light generating devices 110, a flexible substrate 30, a first light-responsive material 1040, a second light generating device 120, and a control system 300.

Especially, in embodiments, the plurality of first light generating devices 110 may comprise one or more solid state light sources. More especially, the plurality of first light generating devices 110 may, in embodiments, be configured to generate first device light 111. Further, in embodiments, the first device light 111 may have intensity at one or more wavelengths in the visible wavelength range, including the first wavelength λ1. In embodiments, the plurality of first light generating devices 110 may at least partly be embedded in the first light-responsive material 1040. Additionally or alternatively, in embodiments, the plurality of first light generating devices 110 may be configured in an array. In specific embodiments, the plurality of first light generating devices 110 may be configured in an array of solid state light sources.

Yet further, in embodiments, the flexible substrate 30 may be configured to support the plurality of first light generating devices 110. Especially, in embodiments, the flexible substrate 30 may comprise a flexible printed circuit board (PCB).

In embodiments, the first light-responsive material 1040 may comprise a first liquid-crystalline elastomer 1041. Especially, in embodiments, the first light-responsive material 1040 may comprise (a) one or more of a polycarbonate, a poly(methyl methacrylate) (PMMA), a glass, (b) a liquid-crystalline elastomer and optionally (c) a hydrogel. Further, in embodiments, the first light-responsive material 1040 may be responsive to radiation having a second wavelength λ2, such that the first light-responsive material 1040 under radiation having the second wavelength λ2 may at least temporarily expand or shrink. Yet further, in embodiments, the first light-responsive material 1040 may be arranged in contact with the flexible substrate 30 such that an expansion or shrinkage of the first light-responsive material 1040 may lead to a conformational change of the flexible substrate 30. Reference 1100 may refer to an arrangement of the flexible substrate 30 together with the plurality of first light generating devices 110, and the first (and/or second) light-responsive material 1040 (and/or 2040).

Especially, in embodiments, the first light-responsive material 1040 may be configured in a light-receiving relationship with the second light generating device 120. Further, the second device light 121 may, in embodiments, have a radiant flux selected from the range of 35-40 mW/cm², relative to a surface 1042 of the first light-responsive material 1040. In embodiments, the second light generating device 120 may comprise a solid state light source.

Further, in embodiments, the light generating system 1000 may be configured to generate system light 1001. Yet further, in embodiments, the system light 1001 may comprise at least part of the first device light 111. Furthermore, the system light may, in embodiments, have a system light optical axis Os. Further, in embodiments, the second device light may have a second optical axis O2. Yet further, in embodiments, the system optical axis Os and the second optical axis O2 may have a first mutual angle α1. Especially, in embodiments, α1 may be selected from the range of 145-225°.

In embodiments, the control system 300 may be configured to control one or more of a beam shape and a beam direction of a beam of system light 1001 by controlling the second light generating device 120.

Furthermore, in embodiments, the first device light 111 may not provide a stimulus to the first light-responsive material 1040. Additionally or alternatively, the one or more solid state light sources may comprise LED dies with a cross-sectional area of ≤1 mm².

Further, in embodiments, the light generating system 1000 may provide the first device light 111. Especially, the first device light 111 may have a first spectral power distribution (see FIG. 1C) having no intensity at the second wavelength λ2, i.e. less than 0.1% of its spectral power.

In embodiments, the flexible substrate 30 in dependence of the second device light 121 may comprise at least a first conformation (see FIG. 1A, (I)) wherein the flexible substrate 30 may have a first radius r1. Further, the flexible substrate 30 in dependence of the second device light 121 may comprise at least a second conformation (see FIG. 1A, (II) and (III)) wherein the flexible substrate 30 may have a second radius r2. In embodiments, the first conformation, wherein the flexible substrate 30 may have a first radius r1 may especially be a planar conformation (see FIG. 1A, (I)), i.e. r1 may be infinite. Further, in other embodiments, the second conformation, wherein the flexible substrate 30 may have a second radius r2 may especially be a curved conformation, i.e. a convex (see FIG. 1A, (II) and FIG. 2 (III)) or a concave conformation (see FIG. 1A, (III)). Yet further, in embodiments, r1/r2≥1.1 or r1/r2≤0.9.

The first light-responsive material 1040 may, in embodiments, be arranged in contact with the flexible substrate 30 on a frontside 31 of the flexible substrate 30 (see FIG. 1B, (I) and (III)). Additionally or alternatively, in embodiments, the first light-responsive material 1040 may be arranged in contact with the flexible substrate 30 on a backside 32 of the flexible substrate 30 (see FIG. 1B, (II) and (IV)).

Referring to FIG. 1B (III) and (IV), in embodiments, the light generating system 1000 may further comprise a third light generating device 130 and a second light-responsive material 2040.

Especially, in embodiments, the second light-responsive material 2040 may comprise a second liquid-crystalline elastomer 2041. Further, in embodiments, the second light-responsive material 2040 may be responsive to radiation having a third wavelength λ3 such that the second light-responsive material 2040 under radiation having the third wavelength λ3 may at least temporarily expand or shrink. Yet further, in embodiments, the second light-responsive material 2040 may be arranged in contact with the flexible substrate 30 or in contact with the first light-responsive material 1040, such that an expansion or shrinkage of the second light-responsive material 2040 may lead to a conformational change of the flexible substrate 30. Especially, in embodiments, the first light-responsive material 1040 and the second light-responsive material 2040 may be arranged on opposite sides of the flexible substrate 30 (see FIG. 1B, (IV)). In specific embodiments, the first light-responsive material 1040 and the second light-responsive material 2040 may be mixed (see FIG. 1B, (III)). Furthermore, in embodiments, λ2≠λ3. Yet further, in embodiments, the first light-responsive material 1040 and the second light-responsive material 2040 may have light responsiveness that may differ in direction.

Furthermore, the third light generating device 130 may, in embodiments, be configured to generate third device light 131. Especially, in embodiments, the third device light 131 may have a radiant flux selected from the range of 15-60 mW/cm², relative to a surface 2042 of the second (and/or first) light-responsive material, such as selected from the range of 30-50 mW/cm², like from the range of 35-40 mW/cm². More especially, in embodiments, the third device light 131 may have a third spectral power distribution (see FIG. 1C) including intensity at the third wavelength λ3. Further, in embodiments, the second light-responsive material 2040 may be configured in a light-receiving relationship with the third light generating device 130.

Yet further, the control system 300 may, in embodiments, be configured to control one or more of a beam shape and beam direction of a beam of system light 1001, by controlling the second light generating device 120 and the third light generating device 130.

In embodiments, the first device light 111 may not provide a stimulus to the second light-responsive material 2040.

Referring to FIG. 1C, in embodiments, the second light generating device 120 may be configured to generate second device light 121 with second wavelength λ2.

Reference R2 may refer to a response curve of the first light-responsive material. Note that there is no spectral overlap with the first device light 111, i.e. less than 0.1% of its spectral power is at λ2. Reference R3 may refer to a response curve of the second light-responsive material. Note that there is also no spectral overlap with the first device light 111, i.e. less than 0.1% of its spectral power is at λ3.

FIG. 2 schematically depicts some embodiments of the light generating system 1000. Especially, in embodiments, the light generating system 1000 may comprise an optical component 400. More especially, in embodiments, the optical component 400 may be configured downstream of the plurality of first light generating devices 110. Further, the optical component 400 may, in embodiments, be selected from a lens, a reflector, a collimator, and a lightguide.

In embodiments, at least one of the plurality of first light generating devices 110 may be configured to provide the first device light 111 with a first optical axis Od1. Further, the optical component 400 may, in embodiments have an optical component optical axis Oc1. Yet further, in embodiments, the control system 300 may be configured to control one or more of a second mutual angle α2 of the first optical axis Od1 and the optical component optical axis Oc1, and a first distance d1 between the first optical axis Od1 and the optical component optical axis Oc1, by controlling the second light generating device 120.

In other embodiments, one end of the flexible substrate 30 may be fixed (see FIG. 2 (I and (II)). For instance, at one side a fixating element 470 may be configured. This may have the effect that the stretching may essentially at least be in a direction away from the fixating element.

Additionally or alternatively, the optical component 400 may be configured to change one or more of the shape and size of the beam of system light 1001 (see FIG. 2 (II) and (III)).

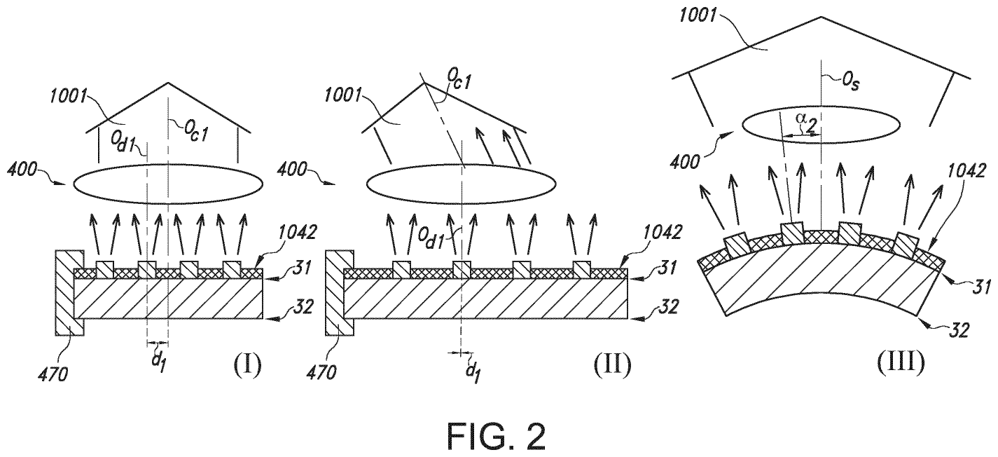

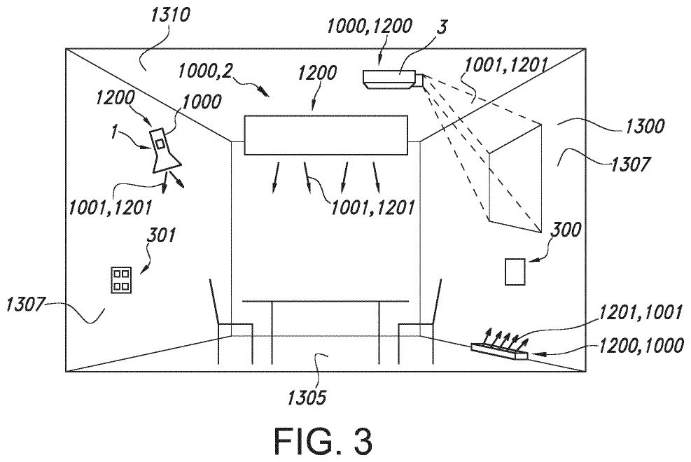

FIG. 3 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 3 also schematically depicts an embodiment of lamp 1 comprising the light generating system 1000. Reference 3 indicates a projector device or projector system, which may be used to project images, such as at a wall, which may also comprise the light generating system 1000. Hence, FIG. 3 schematically depicts embodiments of a lighting device 1200 selected from the group of a lamp 1, a luminaire 2, a projector device 3, a disinfection device, a photochemical reactor, and an optical wireless communication device, comprising the light generating system 1000 as described herein. In embodiments, such lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001. Reference 1300 indicates a space, such as a room, wherein reference 1307 corresponds to the walls of the room, reference 1305 corresponds to the floor, and reference 1310 corresponds to the ceiling.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A lighting device comprising a light generating system;
the light generating system comprising a plurality of first light generating devices, a flexible substrate, a first light-responsive material, a second light generating device, and a control system; wherein:
the plurality of first light generating devices comprise one or more solid state light sources; wherein the plurality of first light generating devices are configured to generate first device light;
the flexible substrate is configured to support the plurality of first light generating devices;
the first light-responsive material comprises a first liquid-crystalline elastomer; wherein the first light-responsive material is responsive to radiation having a second wavelength such that the first light-responsive material under radiation having the second wavelength at least temporarily expands or shrinks; wherein the first light-responsive material is arranged in contact with the flexible substrate such that an expansion or shrinkage of the first light responsive material leads to a conformational change of the flexible substrate;
the second light generating device is configured to generate second device light having a second spectral power distribution including intensity at the second wavelength;
wherein the first light-responsive material is configured in a light-receiving relationship with the second light generating device;
the light generating system is configured to generate system light comprising at least part of the first device light;
the control system is configured to control one or more of a beam shape and beam direction of a beam of system light (1001) by controlling the second light generating device; and wherein:
the lighting device is selected from the group of a lamp, a luminaire, a projector device, a disinfection device, a photochemical reactor, and an optical wireless communication device.

2. The lighting device according to claim 1, wherein the first device light has a first spectral power distribution having no intensity at the second wavelength.

3. The lighting device according to claim 1, wherein the system light has a system light optical axis, wherein the second device light has a second optical axis, wherein the system optical axis and the second optical axis have a first mutual angle selected from the range of 145-225°.

4. The lighting device according to claim 1, wherein the second light generating device is configured to generate the second device light having a radiant flux selected from the range of 35-40 mW/cm², relative to a surface of the first light-responsive material.

5. The lighting device according to claim 1, wherein the second light generating device comprises a solid state light source; wherein the plurality of first light generating devices are configured to generate first device light having intensity at one or more wavelengths in the visible wavelength range.

6. The lighting device according to claim 1, wherein the flexible substrate comprises a flexible printed circuit board.

7. The lighting device according to claim 1, wherein the plurality of first light generating devices are at least partly embedded in the first light-responsive material.

8. The lighting device according to claim 1, wherein the first light responsive material comprises (i) one or more of a polycarbonate, a poly(methyl methacrylate), and a glass, (ii) a liquid crystalline elastomer, and (iii) a hydrogel.

9. The lighting device according to claim 1, wherein the plurality of first light generating devices are configured in an array of solid state light sources.

10. The lighting device according to claim 1, wherein the flexible substrate in dependence of the second device light comprises at least a first conformation wherein the flexible substrate has a first radius and a second conformation wherein the flexible substrate has a second radius, wherein r1/r2≥1.1 or r1/r2≤0.9.

11. The lighting device according to claim 1, further comprising an optical component configured downstream of the plurality of first light generating devices.

12. The lighting device according to claim 11, wherein at least one of the plurality of first light generating devices is configured to provide the first device light with a first optical axis, wherein the optical component has an optical component optical axis wherein the control system is configured to control one or more of (i) a second mutual angle of the first optical axis and the optical component optical axis, and (ii) a first distance between the first optical axis and the optical component optical axis, by controlling the second light generating device.

13. The lighting device according to claim 11, wherein the optical component is selected from a lens, a reflector, a collimator, and a lightguide.

14. The lighting device according to claim 1, further comprising a third light generating device and a second light-responsive material;
the second light-responsive material comprises a second liquid-crystalline elastomer; wherein the second light-responsive material is responsive to radiation having a third wavelength such that the second light-responsive material under radiation having the third wavelength at least temporarily expands or shrinks; wherein the second light-responsive material is arranged in contact with the flexible substrate or in contact with the first light responsive material, such that an expansion or shrinkage of the second light responsive material leads to a conformational change of the flexible substrate; wherein λ2≠λ3;
the first light responsive material and the second light responsive material have light responsiveness that differ in direction;
the third light generating device is configured to generate third device light having a third spectral power distribution including intensity at the third wavelength; wherein the second light-responsive material is configured in a light-receiving relationship with the third light generating device; and
the control system is configured to control one or more of a beam shape and beam direction of a beam of system light by controlling the second light generating device and the third light generating device.

15. The lighting device according to claim 9, wherein the solid-state light sources comprise micro-LEDs.
